(19) United States
(12) Patent Application Publication
(10) Pub. No.: US 2026/0347626 A1
(43) Pub. Date: Nov. 5, 2026

(54) Highly Conductive Polymer Thick Film Composition

(71) Applicant: Celanese Mercury Holdings Inc., Wilmington, DE (US)

(72) Inventors: Hee Hyun Lee, Hockessin, DE (US); Fred E. Nagle, Landenberg, PA (US)

(21) Appl. No.: 19/643,943

(22) Filed: Apr. 10, 2026

Related U.S. Application Data
(60) Provisional application No. 63/788,425, filed on Apr. 14, 2025.

(51) Int. Cl. C09D 5/24; C08J 7/04; C08J 7/044; C08K 9/04; C09D 7/40; C09D 7/62; C09D 127/06; C09D 129/04; C09D 131/04; H05K 1/09

(52) U.S. Cl. CPC C09D 5/24; C08J 7/0427; C08J 7/044; C09D 7/62; C09D 7/68; C09D 7/69; C09D 127/06; C09D 129/04; C09D 131/04; H05K 1/095; C08J 2427/06; C08J 2429/04; C08J 2431/04; C08K 9/04; C08K 2201/001; C08K 2201/005; H05K 2201/10098

(57) ABSTRACT

A thick film composition comprising a particulate material containing a plurality of conductive particles dispersed within an organic medium is provided. The organic medium contains a polymeric resin that includes a hydroxy-functional polymer and at least one organic solvent. The polymeric resin constitutes from about 1 wt. % to about 10 wt. % of the composition. The composition further exhibits a resistivity of about 5 mOhm/sq/mil or less after drying the composition at a temperature of 140 °C for 10 minutes.

### RELATED APPLICATION

The present application is based upon and claims priority to U.S. Provisional Patent Application Ser. No. 63/788,425, having a filing date of Apr. 14, 2025, which is incorporated herein by reference.

### BACKGROUND OF THE DISCLOSURE

Conductive polymer thick film compositions are commonly employed in printed electronics to produce devices such as antenna products. Typically, such products are formed by printing the composition onto a non-conductive substrate in a predetermined circuit pattern and thereafter drying the composition to remove organic solvent contained within the composition. Circuit performance is dependent on the conductivity of the printed antenna and the resistance of the circuit. Namely, the lower the resistivity (inverse of conductivity), the better the performance of any polymer thick film composition used is such circuitry. Unfortunately, efforts at improving the conductivity of polymer thick film compositions often have an adverse impact on other properties, such as adhesion to a substrate and/or the ability of the composition to be easily printed. As such, a need currently exists for a polymer thick film composition that is highly conductive, yet also demonstrates other desirable properties.

### SUMMARY OF THE DISCLOSURE

In accordance with one embodiment of the present disclosure, a thick film composition is disclosed that comprises a particulate material containing a plurality of conductive particles dispersed within an organic medium. The organic medium contains a polymeric resin that includes a hydroxy-functional polymer dissolved in at least one organic solvent. The polymeric resin constitutes from about 1 wt. % to about 10 wt. % of the composition. Further, the composition exhibits a resistivity of about 5 mOhm/sq/mil or less after drying the composition at a temperature range of 140 °C for 10 minutes.

Other features and aspects of the present disclosure are set forth in greater detail below.

### DETAILED DESCRIPTION

It is to be understood by one of ordinary skill in the art that the present discussion is a description of exemplary embodiments only, and is not intended as limiting the broader aspects of the present disclosure.

Generally speaking, the present disclosure is directed to a thick film composition that includes a particulate material containing a plurality of conductive particles dispersed within an organic medium. By selectively controlling various aspects of the composition, such as the specific nature and concentration of the particulate material and organic medium, the present inventor has discovered that the resulting composition is capable of achieving a high degree of conductivity, while still maintaining certain properties that allow it to be readily printed onto a substrate and retain excellent adhesion thereto upon drying. The composition may, for instance, exhibit a resistivity of about 5 mΩ/sq/mil or less, in some embodiments from about 1 to about 4.5 mΩ/sq/mil, and in some embodiments, from about 2 to about 4 mΩ/sq/mil, after drying the composition at a temperature of 140 °C for 10 minutes. It should be understood that such resistivity values may also be achieved over a broad temperature range and/or over a range of drying times. For example, the composition may exhibit the resistivity values noted above over a drying temperature range of from 80 °C to 140 °C and/or after a drying time of from 10 minutes to 30 minutes (e.g., 10 minutes, 15 minutes, or 30 minutes). The high degree of conductivity that can be achieved at the wide range of drying temperatures allows versatile printed electronics applications on various plastic substrates such as flexible antenna circuits, heaters, wearable electronics and sensors, etc.

Various embodiments of the present disclosure will now be described in more detail.

### I. Composition

### A. Particulate Material

While the amount may vary based on the desired characteristics, the particulate material (e.g., powder) typically constitutes from about 40 wt. % to about 95 wt. %, in some embodiments, from about 50 wt. % to about 90 wt. %, in some embodiments from about 55 wt. % to about 85 wt. %, and in some embodiments, from about 60 wt. % to about 80 wt. % of the composition.

The particulate material includes a plurality of conductive particles. Typically, such particles include a conductive material having an electrical conductivity of about 7.00×10⁶ Siemens (S)/m or more, in some embodiments about 8.50×10⁶ S/m or higher, and in some embodiments, about 1.00×10⁷ S/m or higher, as determined at a temperature of 293 K. For example, the conductive material may include a metal, such as aluminum, nickel, copper, silver, gold, molybdenum, magnesium, tungsten, cobalt, zinc, platinum, palladium, as well as alloys or mixtures thereof. Silver particles are particularly beneficial for use in the composition of the present disclosure. Regardless of the specific material employed, it may be desirable to selectively control the size distribution of the conductive particles to achieve a beneficial combination of high conductivity and good printability. For example, the median size or diameter (“D50” particle size) of the conductive particles may be from about 0.3 to about 5 micrometers, in some embodiments from about 0.4 to about 4 micrometers, in some embodiments from about 0.6 to about 2 micrometers, in some embodiments from about 0.7 to about 1.5 micrometers, and in some embodiments, from about 0.8 to about 1.2 micrometers, such as determined using laser diffraction techniques in accordance with ISO 13320:2009 (e.g., with a Microtrac S3500 particle size distribution analyzer). The particles may also have a narrow size distribution. That is, at least about 60% by volume of the particles, in some embodiments at least about 70% by volume of the particles, and in some embodiments, at least about 80% by volume of the particles may have a size within the ranges noted above. For example, the D10 particle size (10% by volume of the particles have a size lower than the assigned value) is typically about 0.3 micrometers or more, and in some embodiments, about 0.4 micrometers or more. Likewise, the D90 particle size (90% by volume of the particles have a size lower than the assigned value) is typically about 5 micrometers or less, and in some embodiments, less than about 3 micrometers. The conductive particles may have any desired shape, such as granular, nodular, flake, platelet etc. When flakes or platelets are employed, for example, the diameter of the particles may have the size characteristics noted above, but the particles may also have a relatively high aspect ratio (e.g., median diameter divided by median thickness), such as about 4 or more, in some embodiments about 10 or more, and in some embodiments, from about 40 to about 250.

In certain embodiments, the particulate material may also contain a surface treatment coated onto at least a portion of the conductive particles. Among other things, the surface treatment may help minimize agglomeration and protect the particles until the composition is dried. The surface treatment may, for example, contain a fatty acid and/or a salt thereof. The fatty acid may generally be any saturated or unsaturated acid having a carbon chain length of from 8 to 38 carbon atoms, in some embodiments from 10 to 24 carbon atoms, and in some embodiments, from about 12 to about 22 carbon atoms. Suitable fatty acids may include, for instance, lauric acid, myristic acid, behenic acid, oleic acid, palmitic acid, stearic acid, ricinoleic acid, capric acid, neodecanoic acid, hydrogenated tallow fatty acid, hydroxy stearic acid, the fatty acids of hydrogenated castor oil, erucic acid, coconut oil fatty acid, montanic acid (octacosanoic acid), arachidic acid (arachic acid, icosanic acid, icosanoic acid, n-icosanoic acid), tetracosanoic acid (lignoceric acid), behenic acid (docosanoic acid), hexacosanoic acid (cerotinic add), melissic acid (triacontanoic acid), erucic acid, cetoleic acid, brassidic acid, selacholeic acid, nervonic acid, etc., as well as mixtures thereof. Besides fatty acids and fatty acid salts, the surface treatment may also include hydrophilic polymers, such as polyvinyl alcohol, poly(N-vinyl-2-pyrrolidone), polyethylene glycol, polyacrylic acid, etc. Besides fatty acids, fatty acid salts and hydrophilic polymers, the surface treatment may also include fatty amines. When employed, the surface treatment may be employed in an amount of from about 0.05 wt. % to about 5 wt. %, and in some embodiments, from about 0.1 wt. % to about 3 wt. % of the composition.

### B. Organic Medium

The organic medium typically constitutes from about 5 wt. % to about 60 wt. %, in some embodiments, from about 10 wt. % to about 50 wt. %, in some embodiments from about 15 wt. % to about 45 wt. %, and in some embodiments, from about 20 wt. % to about 40 wt. % of the composition. One or more polymeric resins may also be employed within the organic medium to help ensure an adequate level of adhesion of the composition to a substrate without adversely impacting other properties, such as its conductivity, printability, etc. Typically, polymeric resin(s) constitute from about 1 wt. % to about 40 wt. %, in some embodiments from about 5 wt. % to about 30 wt. %, and in some embodiments, from about 10 wt. % to about 25 wt. % of the organic medium, as well from about 1 wt. % to about 10 wt. %, in some embodiments from about 2 wt. % to about 8 wt. %, and in some embodiments, from about 3 wt. % to about 7 wt. % of the overall composition.

The polymeric resin may include at least one hydroxy-functional polymer which, among other things, can help ensure that the resulting composition is able to achieve good adherence to a substrate and remain resistant to scratches, moisture, etc. The degree of hydrolysis may be selected to achieve synergistic balance between various properties of the composition. For example, the Hydroxyl Value, which is defined as the number of milligrams of potassium hydroxide required to neutralize acetic acid taken up on acetylation of one gram of the polymer, may range from about 50 to about 150, in some embodiments from about 60 to about 120, and in some embodiments, from about 65 to about 100, such as determined in accordance with ASTM E222-23. The hydroxyl functionality can be incorporated into the polymer through the use of one or more hydroxyl-functional monomers, such as hydroxyl-functional (meth)acrylic monomers, vinyl monomers (e.g., vinyl alcohol), etc. The hydroxyl functionality can improve solubility of the polymer. Suitable hydroxyl-functional (meth)acrylic monomers may include, for instance, hydroxy alkyl (meth)acrylates having 2 to 4 carbon atoms in the hydroxy-alkyl group including hydroxyethyl (meth)acrylate, hydroxypropyl (meth)acrylate, 4-hydroxybutyl (meth)acrylate, etc.

Other monomers may also be employed in forming the polymer, such as vinyl acetate, vinyl chloride, vinylidene chloride, vinyl acetyl, amides, acrylamides, aliphatic olefins (e.g., ethylene), aromatic olefins (e.g., styrene), urethanes, esters, ethers, etc., as well as combinations thereof. In some cases, it may be desired that the hydroxy-functional polymer also contains other functional groups, such as carboxyl functional groups and/or halogen functional groups to help improve performance. In such embodiments, the polymer may be a copolymer that is derived from one or more hydroxy-functional monomers and one or more monomers to provide other functionality. For example, carboxyl functional groups may be provided by a carboxylic acid ester monomer (e.g., vinyl acetate) and halogen functional groups may be provided by a halogenated monomer (e.g., vinyl chloride, vinylidene chloride, etc.). In one particular embodiment, for example, the hydroxy-functional polymer may be a terpolymer derived from vinyl chloride, vinyl acetate, and vinyl alcohol. The vinyl chloride content of the terpolymer may range from about 75 mol. % to about 96 mol. %, in some embodiments from about 80 mol. % to about 94 mol. %, and in some embodiments, from about 85 mol. % to about 92 mol. %; the vinyl acetate content of the terpolymer may range from about 1 mol. % to about 20 mol. %, in some embodiments from about 2 mol. % to about 15 mol. %, and in some embodiments, from about 3 mol. % to about 6 mol. %; and the vinyl alcohol content of the terpolymer may range from about 0.1 mol. % to about 5 mol. %, in some embodiments from about 0.5 mol. % to about 4 mol. %, and in some embodiments, from about 1 mol. % to about 3 mol %. Techniques for preparing such terpolymers are well known in the art and described, for example, in U.S. Pat. Nos. 3,157,563 and 4,647,506, which are incorporated herein by reference.

The organic medium may also include one or more organic solvents to dissolve the polymeric resin, help disperse the particulate material, and ensure that the composition can be readily applied to a substrate. Typically, organic solvent(s) constitute from about 60 wt. % to about 99 wt. %, in some embodiments from about 70 wt. % to about 95 wt. %, and in some embodiments, from about 75 wt. % to about 90 wt. % of the organic medium, as well from about 10 wt. % to about 40 wt. %, in some embodiments from about 15 wt. % to about 35 wt. %, and in some embodiments, from about 20 wt. % to about 30 wt. % of the overall composition. Suitable organic solvents may include, for instance, monobasic esters (e.g., ethyl acetate, butyl acetate, 2-butyoxyethyl acetate, methoxy propyl acetate, etc.), dibasic esters (e.g., ethylene glycol diacetate), glycols (e.g., hexylene glycol, ethylene glycol diacetate, etc.), alcohols (e.g., terpineol), glycol ethers (e.g., diethylene glycol monobutyl ether, dipropylene glycol monomethyl ether), ketones (e.g., diamyl ketone, 5-ethyl-2-nonanone3-methyl-5-propylcyclohexanone, 2-methyl-4-nonanone, C-11 ketone etc.), esters, aromatic hydrocarbons (e.g., benzene, toluene, xylene, etc.), saturated hydrocarbons (e.g., hexane, cyclohexane, heptane, tetradecane), ethers (e.g., diethyl ether, tetrahydrofuran, dioxane), chlorinated hydrocarbons (e.g., dichloroethane, trichloroethylene, chloroform, dichloromethane, etc.), and so forth, as well as mixtures of any two or more thereof. Typically, the boiling point of organic solvent(s) included within the organic medium is about 150 °C or more, in some embodiments from about 160 °C to about 300 °C, and in some embodiments, from about 175 °C to about 250 °C

### C. Other Components

In addition to the particulate material and organic medium, the composition may also contain a variety of other components, such as a thickener, stabilizer, viscosity modifier, dispersing agent, wetting agent, thixotropic agent, and other conventional additives (for example, colorants, preservatives, or antioxidants), etc. In certain embodiments, for example, the composition may contain a dispersing agent, such as in an amount of from about 0.01 wt. % to about 2 wt. %, in some embodiments from about 0.05 wt. % to about 1 wt. %, and in some embodiments, from about 0.1 wt. % to about 0.5 wt. % of the overall composition. Suitable dispersing agents may include, for instance, phosphorus ester salts of amino-containing oligomers or polymers, such as, for example, phosphorus ester salts of optionally fatty acid-modified or alkoxylated (more particularly ethoxylated) polyamines, phosphorus ester salts of epoxide-polyamine adducts, phosphorus ester salts of amino-containing acrylate or methacrylate copolymers, and phosphorus ester salts of acrylate-polyamine adducts; mono-esters or diesters of phosphoric acid, such as, for example, monoesters or diesters of phosphoric acid with alkyl, aryl, aralkyl or alkylaryl alkoxylates (e.g. phosphoric monoesters or diesters of nonylphenol ethoxylates, isotridecyl alcohol ethoxylates, alkylene oxide polyethers prepared starting from butanol), monoesters or diesters of phosphoric acid with polyesters (e.g. lactone polyesters, such as caprolactone polyesters or mixed caprolactone/valero-lactone polyesters); acidic dicarboxylic monoesters, such as acidic dicarboxylic monoesters (more particularly of succinic acid, maleic acid or phthalic acid) with alkyl, aryl, aralkyl or alkylaryl alkoxylates (e.g. nonylphenol ethoxylates, isotridecyl alcohol ethoxylates or alkylene oxide polyethers prepared starting from butanol); polyurethane-polyamine adducts; polyalkoxylated mono-amines or diamines (e.g. ethoxylated oleylamine or alkoxylated ethylenediamine); reaction products of unsaturated fatty acids with monoamines, diamines and polyamines, amino alcohols, and unsaturated 1,2-dicarboxylic acids and their anhydrides and salts thereof and reaction products with alcohols and/or amines.

### II. Laminate Structure

The highly conductive composition of the present disclosure may be deposited onto a variety of different substrates as is known in the art to form a laminate structure (e.g., circuit pattern). The substrate is typically non-conductive and may be formed from a polymeric material, such as a polyester (e.g., polyethylene terephthalate), polymethyl methacrylate, polyethylene, polypropylene, polycarbonate, epoxy, polyimide, polyamide, glass, alumina or the like. The deposition of the composition onto the substrate may be accomplished by techniques such as printing (e.g., screen printing, stencil printing, flexographic printing, Gravure printing, etc.), syringe dispensing, spray, dipping or coating, and so forth. The composition may uniformly coat a surface of the substrate or likewise be applied in a certain pattern in which the composition is only disposed on certain portion(s) of the substrate surface. The pattern may, for example, be configured to form an antenna, interconnect pattern, etc.

Once applied to the substrate, the composition can then be dried to remove solvent(s), which causes the conductive particles to pack together and form a conductive circuit pattern on the substrate. One particular advantage of the composition of the present disclosure is that it can be dried at a relatively low temperature, which is typically lower than the boiling point of one or more organic solvents employed in the composition. For example, the composition can be dried at a temperature of from about 80 °C to about 170 °C, in some embodiments from about 100 °C to about 160 °C, and in some embodiments, from about 110 °C to about 150 °C. When dried at such temperatures, the drying time may range from about 0.5 to about 60 minutes, in some embodiments from about 1 to about 40 minutes, and in some embodiments, from about 2 to about 20 minutes. Regardless, after drying the deposited composition of the present disclosure, a circuit pattern is formed and adhered to a substrate. The resulting circuit pattern may be employed in a wide range of articles, such as RFID devices, Membrane Touch Switches, Appliance Circuitry, etc. Such products are typically used as the printed antenna of the cell. In such cases, an antenna pattern of the composition is printed on top of the appropriate substrate.

The following test methods may be employed according to the present disclosure.

### Test Methods

Resistivity: The resistivity of the composition can be calculated according to techniques known in the art. For example, the composition may be disposed in a serpentine line pattern on a polyester substrate. The line pattern may have a width of 1 mm, a length of 600 mm comprising 600 squares. The line pattern may then be dried in a box oven at a temperature of 140 °C for about 10 minutes. The line pattern may have a thickness of 4μm after the drying. The resistance of the line pattern comprising 600 squares may then be measured with a digital multimeter (Model Fluke 75III, Fluke corporation). Thickness of dried line pattern may be measured with a stylus profilometer (Model Tencor® P-17, KLA corporation). Resistivity (mΩ/sq/mil) may be calculated by the following equation.

Resistivity (mΩ/sq/mil)=[Resistance (Ω)×Thickness (μm)×1000]/[Number of squares of serpentine line pattern×25.4 μm)

The present disclosure is further illustrated by, but is not limited to, the following examples.

### Example 1

A composition was prepared by mixing silver powder and an organic medium composed of a hydroxy-functional polymer for 30 minutes on a planetary mixer. A phosphoric acid ester dispersing agent was also added to the organic medium prior to adding silver powder. The composition was further homogenized by three-roll milling to form a uniform mixture. The hydroxy-functional polymer was a vinyl chloride-vinyl acetate-vinyl alcohol terpolymer having a hydroxyl value of 70-77, and the silver powder had a D50 particle size of 0.87 μm, D10 particle size of 0.44 μm, and D90 particle size of 1.56 μm. The silver particles were also coated with a surface treatment that contained stearic acid. A solvent mixture was used to dissolve the polymer prior to adding the silver powder. The solvent mixture contained butyl cellosolve acetate, C-11 ketone, and ethylene glycol diacetate in a weight ratio of 33.3/33.3/33.3, respectively. The resulting composition thus contained 68.80 wt. % of silver particles, 5.21 wt. % of the hydroxy-functional polymer, 8.57 wt. % butyl cellosolve acetate, 8.57 wt. % C-11 ketone, 8.57 wt. % ethylene glycol diacetate, and 0.25 wt. % of the dispersing agent. After drying the composition at 140 °C for 15 minutes according to the test described above, the resistivity was 3.6 mΩ/sq/mil.

### Example 2

A composition was prepared by mixing silver powder and an organic medium composed of a hydroxy-functional polymer for 30 minutes on a planetary mixer. A phosphoric acid ester dispersing agent was also added to the organic medium prior to adding silver powder. The composition was further homogenized as described in Example 1. The hydroxy-functional polymer was a vinyl chloride-vinyl acetate-hydroxypropyl acrylate terpolymer having a hydroxyl value of 90-100, and the silver powder had a D50 particle size of 0.93 μm, D10 particle size of 0.40 μm, and D90 particle size of 1.96 μm. The silver particles were also coated with a surface treatment that contained lauric acid. A solvent mixture was used to dissolve the polymer prior to adding the silver powder. The solvent mixture contained dipropylene glycol methyl ether and C-11 ketone in a weight ratio of 90/10. The resulting composition thus contains 68.5 wt. % of silver particles, 5.6 wt. % of the vinyl chloride-vinyl acetate-hydroxylpropyl acrylate terpolymer, 22.96 wt. % dipropylene glycol methyl ether, 2.55 wt. % C-11 ketone, and 0.39 wt. % of the dispersing agent. After drying the composition at 120 °C for 20 minutes according to the test described above, the resistivity was 2.6 mΩ/sq/mil. The resistivity of the same composition dried at 100 °C for 30 minutes was 2.7 mΩ/sq/mil. The resistivity of the same composition dried at 80 °C for 60 minutes was 4.7 mΩ/sq/mil.

### Example 3

A composition was prepared by mixing silver powder and an organic medium composed of a hydroxy-functional polymer for 30 minutes on a planetary mixer. A phosphoric acid ester dispersing agent was also added to the organic medium prior to adding silver powder. The composition was further homogenized as described in Example 1. The hydroxy-functional polymer was a vinyl chloride-vinyl acetate-hydroxypropyl acrylate terpolymer having a hydroxyl value of 90-100, and the silver powder had a D50 particle size of 1.10 μm, D10 particle size of 0.61 μm, and D90 particle size of 1.91 μm. The silver particles were also coated with a surface treatment that contained stearic acid. A solvent mixture was used to dissolve the polymer prior to adding the silver powder. The solvent mixture contained dipropylene glycol methyl ether and C-11 ketone in a weight ratio of 90/10. The resulting composition thus contains 70.0 wt. % of silver particles, 5.33 wt. % of the vinyl chloride-vinyl acetate-hydroxylpropyl acrylate terpolymer, 21.84 wt. % dipropylene glycol methyl ether, 2.43 wt. % C-11 ketone, and 0.40 wt. % of the dispersing agent. After drying the composition at 120 °C for 20 minutes according to the test described above, the resistivity was 5.0 mΩ/sq/mil. The resistivity of the same composition dried at 140 °C for 10 minutes was 4.6 mΩ/sq/mil.

### Example 4

A composition was prepared by mixing silver powder and an organic medium composed of a hydroxy-functional polymer for 30 minutes on a planetary mixer. A phosphoric acid ester dispersing agent was also added to the organic medium prior to adding silver powder. The composition was further homogenized as described in Example 1. The hydroxy-functional polymer was a vinyl chloride-vinyl acetate-hydroxypropyl acrylate terpolymer having a hydroxyl value of 90-100, and the silver powder had a D50 particle size of 1.68 μm, D10 particle size of 0.72 μm, and D90 particle size of 3.27 μm. The silver particles were also coated with a surface treatment that contained lauric acid. A solvent mixture was used to dissolve the polymer prior to adding the silver powder. The solvent mixture contained dipropylene glycol methyl ether and C-11 ketone in a weight ratio of 90/10. The resulting composition thus contained 60.0 wt. % of silver particles, 7.13 wt. % of the vinyl chloride-vinyl acetate-hydroxylpropyl acrylate terpolymer, 29.23 wt. % dipropylene glycol methyl ether, 3.25 wt. % C-11 ketone, and 0.39 wt. % of the dispersing agent. After drying the composition at 100 °C for 30 minutes according to the test described above, the resistivity was 3.9 mΩ/sq/mil. The resistivity of the same composition dried at 140 °C for 10 minutes was 3.8 mΩ/sq/mil.

### Comparative Example 1

A composition was prepared by mixing silver powder and an organic medium composed of a polymer not containing any hydroxy-functional groups. A phosphoric acid ester dispersing agent was also added to the organic medium prior to adding silver powder. The composition was further homogenized as described in Example 1. The non-hydroxy-functional polymer was a vinyl chloride-acrylonitrile copolymer, and the silver powder had a D50 particle size of 1.10 μm, D10 particle size of 0.61 μm, and D90 particle size of 1.91 μm. The silver particles were also coated with a surface treatment that contained stearic acid. A solvent mixture was used to dissolve the polymer prior to adding the silver powder. The solvent mixture contained dimethyl succinate and dimethyl glutamate in a weight ratio of 33.3/66.7. The resulting composition thus contained 68.38 wt. % of silver particles, 5.58 wt. % of the vinyl chloride/acrylonitrile copolymer, 8.55% dibasic Esters (DBE-4), 17.1% dimethyl glutarate, and 0.39 wt. % of the dispersing agent. After drying the composition at 140 °C for 10 minutes according to the test described above, the resistivity was 14.4 mΩ/sq/mil.

### Comparative Example 2

A composition was prepared by mixing silver powder and an organic medium composed of a polymer not containing any hydroxy-functional groups. A phosphoric acid ester dispersing agent was also added to the organic medium prior to adding silver powder. The composition was further homogenized as described in Example 1. The non-hydroxy-functional polymer was a vinyl chloride-vinyl acetate copolymer, and the silver powder had a D50 particle size of 1.10 μm, D10 particle size of 0.61 μm, and D90 particle size of 1.91 μm. The silver particles were also coated with a surface treatment that contained stearic acid. A solvent mixture was used to dissolve the polymer prior to adding the silver powder. The solvent mixture contained dipropylene glycol methyl ether and C-11 ketone in a weight ratio of 90/10. The resulting composition thus contained 69.0 wt. % of silver particles, 5.52 wt. % of the vinyl chloride/vinyl acetate copolymer, 22.6 wt. % dipropylene glycol methyl ether, 2.51 wt. % C-11 ketone, and 0.38 wt. % of the dispersing agent. After drying the composition at 120 °C for 20 minutes according to the test described above, the resistivity was 12.0 mΩ/sq/mil. The resistivity of the same composition dried at 140 °C for 10 minutes was 5.4 mΩ/sq/mil. These and other modifications and variations of the present disclosure may be practiced by those of ordinary skill in the art, without departing from the spirit and scope of the present disclosure. In addition, it should be understood that aspects of the various embodiments may be interchanged both in whole or in part. Furthermore, those of ordinary skill in the art will appreciate that the foregoing description is by way of example only and is not intended to limit the disclosure so further described in such appended claims.

What is claimed is:

1. A thick film composition comprising a particulate material containing a plurality of conductive particles dispersed within an organic medium, wherein the organic medium contains a polymeric resin that includes a hydroxy-functional polymer and at least one organic solvent, wherein the polymeric resin constitutes from about 1 wt. % to about 10 wt. % of the composition, and further wherein the composition exhibits a resistivity of about 5 mΩ/sq/mil or less after drying the composition at a temperature of 140 °C for 10 minutes.

2. The thick film composition of claim 1, wherein the conductive particles include silver particles.

3. The thick film composition of claim 1, wherein the conductive particles have a D50 size of from about 0.3 to about 5 micrometers.

4. The thick film composition of claim 3, wherein the conductive particles have a D10 size of about 0.3 micrometers or more and a D90 particles size of about 5 micrometers or less.

5. The thick film composition of claim 1, wherein the conductive particles are coated with a surface treatment.

6. The thick film composition of claim 1, wherein the hydroxy-functional polymer has a Hydroxyl Value of from about 50 to about 150.

7. The thick film composition of claim 1, wherein the hydroxy-functional polymer is derived from a hydroxyl-functional (meth)acrylic monomer, vinyl monomer, or a combination thereof.

8. The thick film composition of claim 7, wherein the hydroxy-functional polymer is derived from vinyl alcohol.

9. The thick film composition of claim 1, wherein the hydroxy-functional polymer is further derived from a carboxylic acid ester monomer.

10. The thick film composition of claim 9, wherein the carboxylic acid ester monomer includes vinyl acetate.

11. The thick film composition of claim 1, wherein the hydroxy-functional polymer is further derived from a halogenated monomer.

12. The thick film composition of claim 11, wherein the halogenated monomer includes vinyl chloride, vinylidene chloride, or a combination thereof.

13. The thick film composition of claim 1, wherein the hydroxy-functional polymer is a terpolymer derived from vinyl chloride, vinyl acetate, and vinyl alcohol.

14. The thick film composition of claim 1, wherein organic solvents constitute from about 10 wt. % to about 40 wt. % of the composition.

15. The thick film composition of claim 1, wherein the boiling point of the organic solvent is about 150 °C or more.

16. The thick film composition of claim 1, wherein the composition exhibits a resistivity of about 5 mΩ/sq/mil or less after drying the composition over a temperature range of from 80 °C to 140 °C.

17. A circuit pattern structure comprising the thick film composition of claim 1 disposed on a substrate.

18. The circuit pattern structure of claim 17, wherein the substrate includes a polymeric material.

19. The circuit pattern structure of claim 17, wherein the thick film composition is disposed on the substrate in an antenna pattern.

20. A method for forming the circuit pattern structure of claim 17, the method comprising depositing the composition onto a surface of the substrate, and thereafter drying the composition at a temperature of from about 70 °C to about 170 °C.
